(19) United States
(12) Patent Application Publication
(10) Pub. No.: US 2013/0344712 A1
(43) Pub. Date: Dec. 26, 2013

(54) INTERCONNECTIONS BETWEEN FLEXIBLE AND RIGID COMPONENTS

(71) Applicant: APPLE INC., Cupertino, CA (US)

(72) Inventors: Jared M. KOLE, San Jose, CA (US); Michael B. WITTENBERG, Sunnyvale, CA (US); Shayan MALEK, San Jose, CA (US)

(73) Assignee: APPLE INC., Cupertino, CA (US)

(21) Appl. No.: 13/632,135

(22) Filed: Sep. 30, 2012

Related U.S. Application Data
(60) Provisional application No. 61/663,511, filed on Jun. 22, 2012.

(51) Int. Cl. H05K 1/11

(52) U.S. Cl. 439/67

(57) ABSTRACT

A low-height connectorless interconnection system includes a first substrate, the first substrate having a first plurality of exposed portions of underlying circuit traces and a second substrate, the second substrate having a second plurality of exposed portions of underlying circuit traces. The system further includes a plurality of conductive formations formed on at least one of the first and second pluralities of exposed portions of underlying circuit traces and a clamping member arranged to join the first and second substrate such that the first and second pluralities of exposed portions of circuit traces are in severable electrical communication.

### CROSS-REFERENCE TO RELATED APPLICATIONS

This application claims the benefit of U.S. Provisional Patent Application No. 61/663,511, filed Jul. 22, 2012 and entitled “INTERCONNECTIONS BETWEEN FLEXIBLE AND RIGID COMPONENTS” by KOLE et al., which is incorporated by reference in its entirety for all purposes.

### FIELD OF THE DESCRIBED EMBODIMENTS

The described embodiments relate generally to interconnections, and more particularly, to interconnections between flexible and rigid components in electronic devices.

### BACKGROUND

Conventionally, interconnections between different components of electronic devices are gained through use of dedicated connectors or direct attachment. For example, interconnections between flexible and rigid components of electronic devices often use either dedicated connectors or direct attachment. Dedicated connectors may include any number of standard or non-standard connectors including a housing and a set of electrodes disposed in the housing, with the housing permanently or semi-permanently mounted or coupled to the flexible component. Generally, the housing limits the minimum height of the connector. Accordingly, connectors may be difficult to integrate as overall height, width, or depth of personal electronic devices is sought to be minimized.

Direct attachment offers several advantages over connectors, particularly in low-height or thin devices. Direct attachment methods vary, and can include soldering, adhesives, and conductive films. For example, thermo-compression (hot bar) bonder soldering offers low-height connections, but suffers from several drawbacks, including lack of replaceability of components and difficulty in servicing the connection should an issue arise.

Adhesives and conductive films, including anisotropic conductive film (ACF), are also used in direct attachment. However, as with hot bar bonder soldering, if an issue arises in any number of components many times entire assemblies must be replaced.

### SUMMARY OF THE DESCRIBED EMBODIMENTS

This paper describes various embodiments that relate to severable interconnections between two or more substrates of electronic devices. The substrates may be rigid, semi-rigid, or flexible. The interconnections may promote electrical communication between portion of electrical circuit traces within the two or more substrates.

According to one exemplary embodiment of the present invention, a low-height connectorless interconnection system includes a first substrate, the first substrate having a first plurality of exposed portions of underlying circuit traces and a second substrate, the second substrate having a second plurality of exposed portions of underlying circuit traces. The system further includes a plurality of conductive formations formed on at least one of the first and second pluralities of exposed portions of underlying circuit traces and a clamping member arranged to join the first and second substrate such that the first and second pluralities of exposed portions of circuit traces are in severable electrical communication.

According to another embodiment of the invention, a low-height connectorless interconnection system includes a first substrate, the first substrate having a plurality of exposed portions of underlying circuit traces, a second substrate, the second substrate having a plurality of conductive formations formed thereon in electrical communication with portions of underlying circuit traces, and a clamping member arranged to join the first and second substrate such that the plurality of exposed portions of circuit traces and the plurality of conductive formations are in severable electrical communication.

According to another embodiment of the invention, a method of forming a low-height connectorless interconnection system includes exposing at least a portion of an electrical circuit trace on a first substrate and a second substrate, applying a conductive chemistry onto the exposed electrical circuit traces, processing the applied conductive chemistry to form at least one conductive formation on the exposed portion of the first substrate or the second substrate, and joining the first substrate with the second substrate such that a severable electrical interconnection is formed between the electrical circuit traces of the first and second substrates.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a perspective view of an interconnection, according to an exemplary embodiment of the present invention.

FIG. 2 is an expanded view of the interconnection of FIG. 1.

FIG. 3 is an elevation view of a disassembled interconnection, according to an exemplary embodiment of the present invention.

FIG. 4 is an elevation view of a partially assembled interconnection, according to an exemplary embodiment of the present invention.

FIG. 5 is an elevation view of an alternate disassembled interconnection, according to an exemplary embodiment of the present invention.

FIG. 6 is an elevation view of an alternate partially assembled interconnection, according to an exemplary embodiment of the present invention.

FIG. 7 is an elevation view of an alternate disassembled interconnection, according to an exemplary embodiment of the present invention.

FIG. 8 is an elevation view of an alternate partially assembled interconnection, according to an exemplary embodiment of the present invention.

FIGS. 9A-9F illustrate a portion of a method of interconnecting portions of an electronic device, according to an exemplary embodiment of the present invention.

FIG. 10 is a flow chart of a method of interconnecting portions of an electronic device, according to an exemplary embodiment of the present invention.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

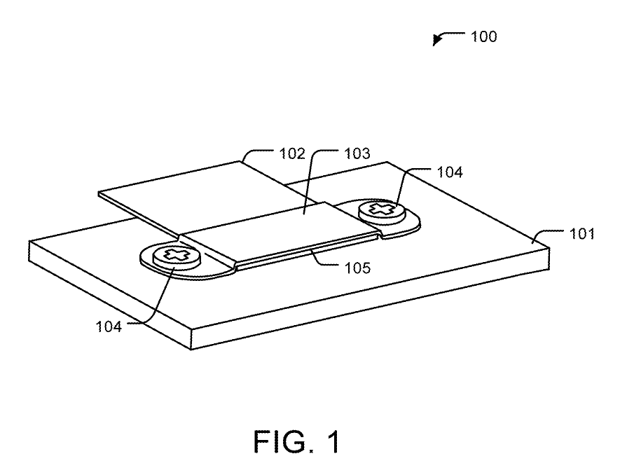

Turning to FIG. 1, a perspective view of an interconnection is illustrated, according to an exemplary embodiment of the present invention. The interconnection 100 may be a low-height interconnection which is connectorless. As used herein, the term connectorless may refer to a connection which lacks a conventional electronic connector or connector housing, or, alternatively, an interconnection which is severable and re-connectable without a permanently attached connector housing.

The interconnection 100 includes a substrate 101. The substrate 101 may be any suitable substrate, including a printed electronic circuit board (PCB). The PCB 101 may be a rigid or semi-rigid PCB having a plurality of circuit traces arranged thereon, embedded therein, or arranged beneath a coverlay protecting said circuit traces. The coverlay may be any suitable coverlay, including a plastic-based film or resist layer arranged on a surface of the PCB 101.

The interconnection 100 further includes a second substrate 102 arranged proximate and in contact with the PCB 101. The second substrate 102 may be any suitable substrate, including a PCB. The PCB 102 may be a rigid, semi-rigid, or flexible PCB having a plurality of circuit traces arranged thereon, embedded therein, or arranged beneath a coverlay protecting said circuit traces. The coverlay may be any suitable coverlay, including a plastic-based film or resist layer arranged on a surface of the PCB 102.

The interconnection 101 further includes a compliance member 105 arranged on the PCB 102. The compliance member 105 may be a member disposed to adhere to the PCB 102. Alternatively, or in combination, the compliance member 105 may be a layer formed of a foam or foam-like material arranged to bias the PCB 102 against the PCB 101, for example, through a biasing, cushioning, or spring-like force.

The interconnection 100 further includes clamping member 103 arranged on the compliance member 105 and in contact with the PCB 101. The clamping member 103 may be fastened to the PCB 101 through fasteners 104. According to one embodiment, the fasteners 104 may be screws or screw-like fasteners. According to other embodiments, the fasteners 104 may be adhesive constructs, clips, bolts, or any other suitable fastener.

The clamping member 103 may be formed of a rigid or semi-rigid material, such as plastic, metal, metal-impregnated plastic, solid amorphously-formed metallic or metal alloy, or any suitable material. According to one embodiment, the clamping member 103 is a metal clamp formed of a continuous piece of metal such as aluminum. According to other embodiments, the clamping member 103 is an injection molded plastic or molded amorphous metal alloy clamp. According to other embodiments, the clamping member 103 is a semi-rigid rubber clamp.

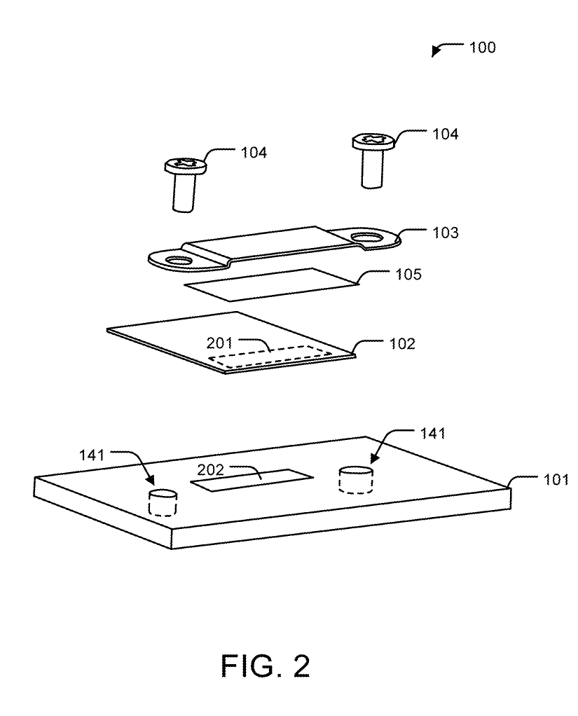

As illustrated, the clamping member 103 is arranged to clamp and hold the compliance member 105 and second substrate 102 against substrate 101. Turning now to FIG. 2, an expanded view of the interconnection of FIG. 1 is illustrated.

As shown, the substrate 104 includes receiving formations 141 configured to receive and engage fasteners 104. The receiving formations 141 may be accurately formed on or in the substrate 101 such that auto-alignment of the substrate 102 in relation to substrate 101 occurs. For example, the substrate 102 may include a plurality of interconnection electrodes 201 arranged on or just beneath a surface thereof. Furthermore, the substrate 101 may include a plurality of interconnection electrodes 202 arranged on or just beneath a surface thereof. The interconnection electrodes 202 may be complementary to the interconnection electrodes 201 such that, when properly aligned and in electrical contact, appropriate electrical interconnections are formed between the substrate 101 and the substrate 102. As such, as the fasteners 104 are inserted through the clamping member 103 and the assembly of the compliance member 105 and substrate 102 are brought into proximity of the receiving formations 141, auto-alignment of the interconnection electrodes 201 and 202 occurs. Further, as fasteners 104 are subsequently fully or partially engaged with the receiving formations 141, suitable interconnections are formed between the substrate 101 and the substrate 102, for example as illustrated in FIG. 1.

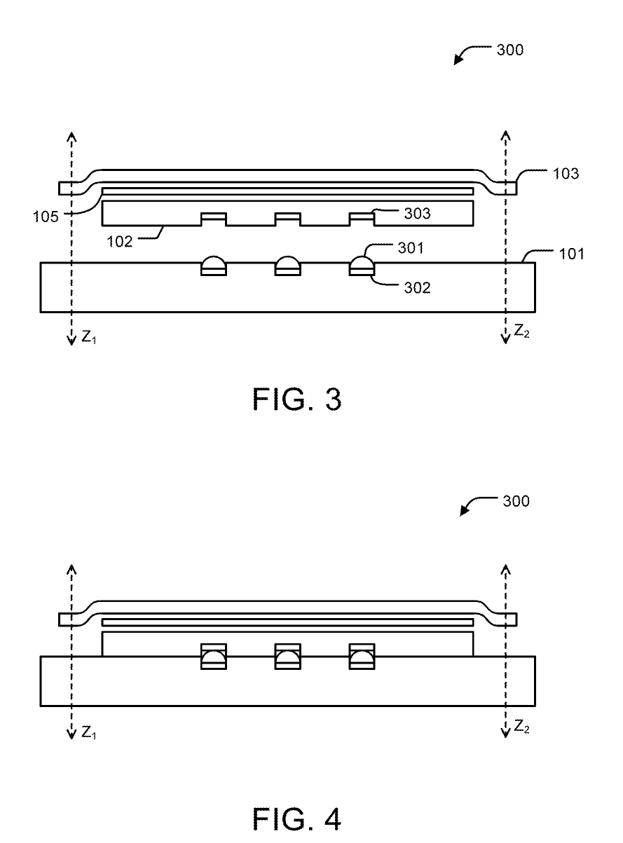

As stated above, the interconnection electrodes 201 and 201 may include a plurality of electrodes arranged on or beneath a surface of the substrates 101 and 102. Turning now to FIGS. 3-8, several examples of suitable interconnection electrode formations are presented. It should be understood that while FIGS. 3-8 illustrate particular examples of interconnection electrode formations, the same may be varied in many ways. As such, the following examples should not be construed as limiting but should instead include all equivalent structures which provide suitable interconnections as described herein.

FIG. 3 is an elevation view of a disassembled interconnection 300, according to an exemplary embodiment of the present invention. As shown, the substrate 101 may include a plurality of interconnection electrodes 302 formed therein. The electrodes 302 may be formed of any suitable electrically conductive material, including copper. The electrodes 302 may be exposed portions of electrical circuit traces formed on or in the substrate 101. The substrate 101 may include receiving formations as illustrated in FIG. 2 and represented here by alignment axes Z₁ and Z₂. Similarly, clamping member 103 may be arranged to receive fasteners which are configured to be received and engaged along alignment axes Z₁ and Z₂.

As shown, the electrodes 302 may each include a conductive formation 301 arranged thereon. The conductive formations 301 may be formed of a conductive material, such as, for example solder. The conductive formations 301 may be in generally hemispherical or hillock formations configured to promote electrical communication between the electrodes 302 and complementary electrodes 303 which are formed in the substrate 102. The electrodes 303 may be formed of any suitable electrically conductive material, including copper. The electrodes 303 may be exposed portions of electrical circuit traces formed on or in the substrate 102.

As illustrated in FIG. 4, upon at least partial assembly of the interconnection 300, the conductive formations 301 promote electrical interconnection between the substrate 101 and the substrate 102. Upon final assembly or at any suitable time, if any number of components interconnected by substrates 101 and 102 need servicing or replacement, the interconnection 300 may be severed, clamping member 103 removed, and service may occur without destroying or damaging the electrodes 302 and 303 and associated conductive formations 302. Thereafter, the entire interconnection 300 maybe reassembled without replacement of the substrate 102 if desired.

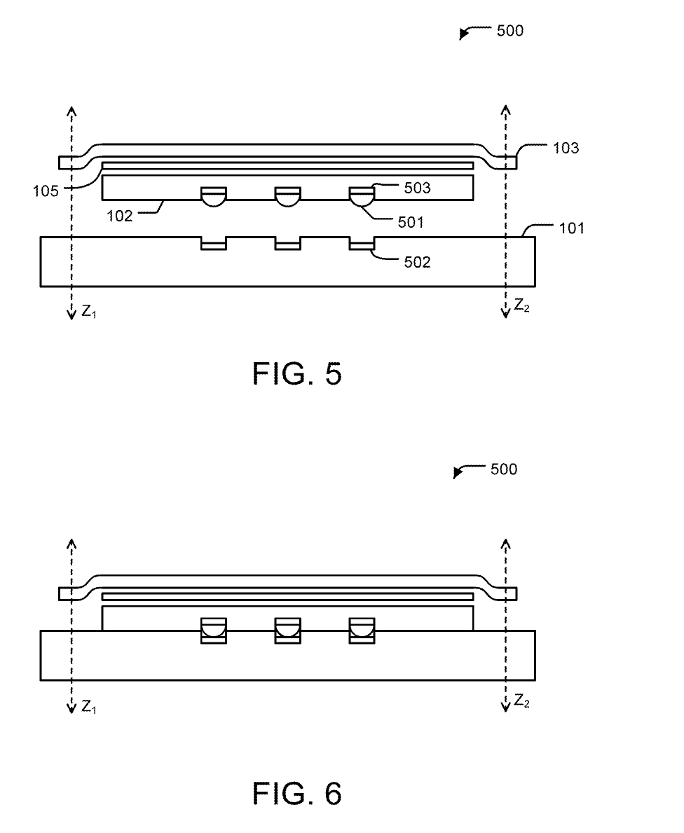

FIG. 5 is an elevation view of an alternate disassembled interconnection 500, according to an exemplary embodiment of the present invention. As shown, the substrate 101 may include a plurality of interconnection electrodes 502 formed therein. The electrodes 502 may be formed of any suitable electrically conductive material, including copper. The electrodes 502 may be exposed portions of electrical circuit traces formed on or in the substrate 101. The substrate 101 may include receiving formations as illustrated in FIG. 2 and represented here by alignment axes Z₁ and Z₂. Similarly, clamping member 103 may be arranged to receive fasteners which are configured to be received and engaged along alignment axes Z₁ and Z₂.

Additionally, the substrate 102 may include a plurality of complementary electrodes 502 formed therein. The electrodes 503 may be formed of any suitable electrically conductive material, including copper. The electrodes 503 may be exposed portions of electrical circuit traces formed on or in the substrate 102.

As shown, the electrodes 503 may each include a conductive formation 501 arranged thereon. The conductive formations 501 may be formed of a conductive material, such as, for example solder. The conductive formations 501 may be in generally hemispherical or hillock formations configured to promote electrical communication between the electrodes 502 and complementary electrodes 503.

As illustrated in FIG. 6, upon at least partial assembly of the interconnection 500, the conductive formations 501 promote electrical interconnection between the substrate 102 and the substrate 101. Upon final assembly or at any suitable time, if any number of components interconnected by substrates 101 and 102 need servicing or replacement, the interconnection 500 may be severed, clamping member 103 removed, and service may occur without destroying or damaging the electrodes 502 and 503 and associated conductive formations 502. Thereafter, the entire interconnection 500 maybe reassembled without replacement of the substrate 102 if desired.

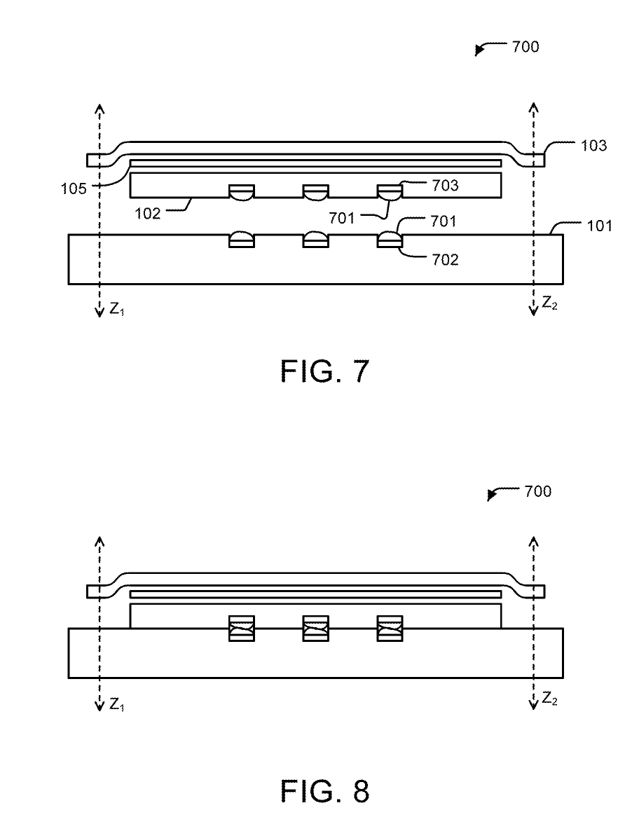

FIG. 7 is an elevation view of an alternate disassembled interconnection 700, according to an exemplary embodiment of the present invention. As shown, the substrate 101 may include a plurality of interconnection electrodes 702 formed therein. The electrodes 702 may be formed of any suitable electrically conductive material, including copper. The electrodes 702 may be exposed portions of electrical circuit traces formed on or in the substrate 101. The substrate 101 may include receiving formations as illustrated in FIG. 2 and represented here by alignment axes Z₁ and Z₂. Similarly, clamping member 103 may be arranged to receive fasteners which are configured to be received and engaged along alignment axes Z₁ and Z₂.

Additionally, the substrate 102 may include a plurality of complementary electrodes 702 formed therein. The electrodes 703 may be formed of any suitable electrically conductive material, including copper. The electrodes 703 may be exposed portions of electrical circuit traces formed on or in the substrate 102.

As shown, the electrodes 502 and 503 may each include conductive formation 501 arranged thereon. The conductive formations 701 may be formed of a conductive material, such as, for example solder. The conductive formations 701 may be in generally hemispherical or hillock formations configured to promote electrical communication between respective conductive formations 701 of the electrodes 702 and complementary electrodes 703.

As illustrated in FIG. 8, upon at least partial assembly of the interconnection 700, the conductive formations 701 promote electrical interconnection between the substrate 102 and the substrate 101. Upon final assembly or at any suitable time, if any number of components interconnected by substrates 101 and 102 need servicing or replacement, the interconnection 700 may be severed, clamping member 103 removed, and service may occur without destroying or damaging the electrodes 702 and 703 and associated conductive formations 702. Thereafter, the entire interconnection 700 maybe reassembled without replacement of the substrate 102 if desired.

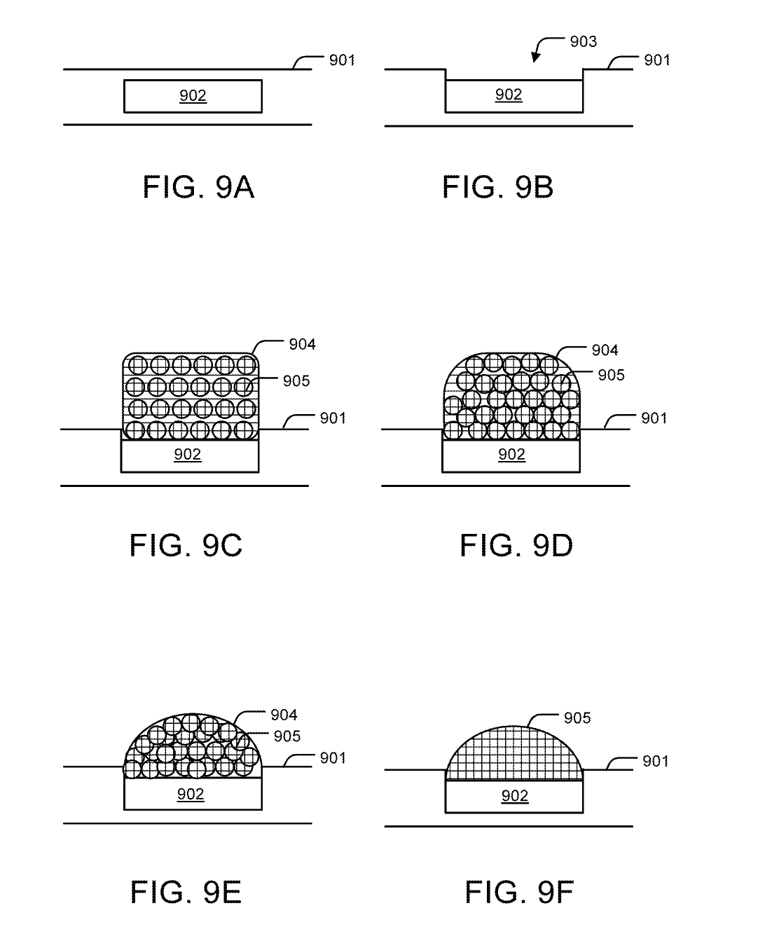

As described above with reference to FIGS. 3-8, conductive formations 301, 501, and 701 may be formed on respective electrodes of the substrates 101 and/or 102. The conductive formations 301, 501, and 701 may be generally hemispherical or hillock shaped, and may protrude beyond an outer surface or coverlay of the substrates 101 and 102 to promote electrical interconnection therebetween. Hereinafter, a more detailed description of methods of forming conductive formations on interconnection electrodes is provided with reference to FIGS. 9A-9F.

FIGS. 9A-9F illustrate a portion of a method of interconnecting portions of an electronic device, according to an exemplary embodiment of the present invention. According to FIG. 9A, a substrate 901 may be provided with underlying electrical circuit traces 902 embedded therein. The electrical circuit traces 902 may be any suitable traces formed on or in a substrate and covered with a portion of the substrate 901, a coverlay, or any desired combination thereof. The method includes providing the substrate 901 with the associated circuit traces 902. According to FIG. 9B, a portion 903 of a coverlay, the substrate 901, or another formation may be removed to expose at least a portion the electrical circuit trace 902. The exposed portion may then be used for interconnection as described above, or alternatively, a conductive formation protruding beyond an outer surface of the substrate 901 may be formed as illustrated in FIGS. 9C-9F.

According to FIG. 9F, a conductive chemical mixture 904 may be dispensed on the exposed portion of the circuit trace 902. The conductive chemical mixture 904 may be any suitable mixture, including but not limited to solder paste, amorphous metal alloys, solder flux impregnated with solder balls, or any other mixture. As illustrated in this embodiment, the conductive chemical mixture 904 comprises a plurality of solder balls 905 dispersed therein.

After dispensing the conductive chemical mixture 904, the substrate 901 and conductive chemical mixture 904 may be reflow or heat processed to promote the conductive chemical mixture 904 to coalesce and form a conductive formation for stable interconnection. For example, as illustrated in FIGS. 9D-9F, three main stages of a typical reflow process may be applied such that solder balls 905 coalesce within the conductive chemical mixture 904 and form a hemispherical or hillock shaped conductive formation 905 illustrated in FIG. 9F.

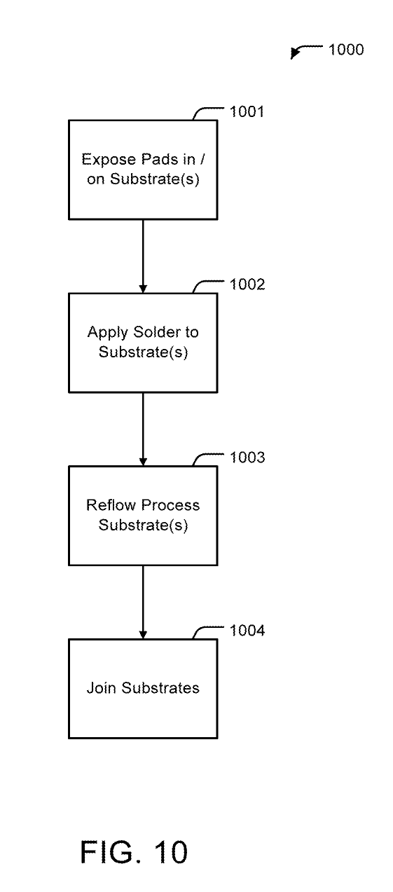

The methodology described above may be applied to a plurality of exposed conductive traces, pads, and/or electrodes to form any desired set of interconnection electrodes. Fore example, FIG. 10 is a flow chart of a method of interconnecting portions of an electronic device, according to an exemplary embodiment of the present invention. As shown the method 1000 includes exposing at least one pad, or a plurality of pads in/on a substrate at block 1001. The exposing may be facilitated through chemical etching, mechanical milling, or any other desired form of removing a portion of material to expose portions of electrical traces on a substrate.

Thereafter, the method 1000 includes applying solder (e.g., conductive chemical mixtures) to the substrate/substrates at block 1002. Upon application, the method 1000 includes reflow or heat processing of the substrate/substrates at block 1003 to form conductive formations thereon. After processing, the substrates may be joined to facilitate interconnection therebetween as described above.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A low-height connectorless interconnection system, comprising:
a first substrate, the first substrate having a first plurality of exposed portions of underlying circuit traces;
a second substrate, the second substrate having a second plurality of exposed portions of underlying circuit traces;
a plurality of conductive formations formed on at least one of the first and second pluralities of exposed portions of underlying circuit traces; and
a clamping member arranged to join the first and second substrate such that the first and second pluralities of exposed portions of circuit traces are in severable electrical communication.

2. The system of claim 1, wherein the first and second pluralities of exposed portions of circuit traces are arranged to electrically interconnect a plurality of electrical components of a personal electronic device.

3. The system of claim 1, wherein the first substrate is a rigid or semi-rigid substrate.

4. The system of claim 3, wherein the rigid substrate is a printed electronic circuit board.

5. The system of claim 1, wherein the second substrate is a semi-rigid or flexible substrate.

6. The system of claim 5, wherein the flexible substrate is a flex printed circuit board.

7. The system of claim 1, further comprising a compliance member arranged between the second substrate and the clamping member, wherein the compliance member is configured to bias the second substrate into stable contact with the first substrate.

8. The system of claim 7, wherein the compliance member is a layer of adhesive foam.

9. The system of claim 7, wherein the compliance member is a layer of adhesive tape.

10. The system of claim 1, wherein the plurality of conductive formations each have a hemispherical or hillock shaped cross-section.

11. The system of claim 10, wherein the plurality of conductive formations are formed of a heat-processed conductive chemistry.

12. The system of claim 11, wherein the heat-processed conductive chemistry is a reflow processed solder paste or a reflow processed amorphous metal alloy.

13. A low-height connectorless interconnection system, comprising:
a first substrate, the first substrate having a plurality of exposed portions of underlying circuit traces;
a second substrate, the second substrate having a plurality of conductive formations formed thereon in electrical communication with portions of underlying circuit traces; and
a clamping member arranged to join the first and second substrate such that the plurality of exposed portions of circuit traces and the plurality of conductive formations are in severable electrical communication.

14. The system of claim 13, wherein the plurality of exposed portions of circuit traces are arranged to electrically interconnect a plurality of electrical components of a personal electronic device.

15. The system of claim 13, wherein the first substrate is a rigid or semi-rigid substrate.

16. The system of claim 15, wherein the rigid substrate is a printed electronic circuit board.

17. The system of claim 13, wherein the second substrate is a flexible substrate.

18. The system of claim 17, wherein the flexible substrate is a flex printed circuit board.

19. The system of claim 13, further comprising a compliance member arranged between the second substrate and the clamping member, wherein the compliance member is configured to bias the second substrate into stable contact with the first substrate.

20. The system of claim 19, wherein the compliance member is a layer of adhesive foam or adhesive tape

21. The system of claim 13, wherein the plurality of conductive formations each have a hemispherical or hillock shaped cross-section.

22. The system of claim 21, wherein the plurality of conductive formations are formed of a heat-processed conductive chemistry of reflow-processed solder paste or reflow processed amorphous metal alloy.

23. A method of forming a low-height connectorless interconnection system, comprising:
exposing at least a portion of an electrical circuit trace on a first substrate and a second substrate;
applying a conductive chemistry onto the exposed electrical circuit traces;
processing the applied conductive chemistry to form at least one conductive formation on the exposed portion of the first substrate or the second substrate; and
joining the first substrate with the second substrate such that a severable electrical interconnection is formed between the electrical circuit traces of the first and second substrates.
